(19) United States
(12) Patent Application Publication
(10) Pub. No.: US 2008/0241425 A1
(43) Pub. Date: Oct. 2, 2008

(54) SYSTEM AND METHOD TO REDUCE REDEPOSITION OF ABLATED MATERIAL

(75) Inventors: Ming Li, Chelmsford, MA (US); Nagaraj Batta, Boston, MA (US)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/694,396

(22) Filed: Mar. 30, 2007

(51) Int. Cl. C23C 14/28

(52) U.S. Cl. 427/596; 118/50.1

(57) ABSTRACT

A laser machining system adapted to reduce redeposition of material ablated from a workpiece. The laser machining system includes: a laser source to generate a pulsed laser beam; optics to relay the pulsed laser beam along a beam path from the laser source to the work piece; a long working distance objective disposed in the beam path; a workpiece holder to hold the workpiece such that an ablation surface of the workpiece is substantially vertical; and a vacuum chamber, including a window that is substantially transmissive to the laser beam. The vacuum chamber is sized and arranged such that the window in disposed in the beam path and the vacuum chamber encloses the workpiece holder in a reduced pressure environment. The long working distance objective substantially focuses the laser beam to a beam spot on an ablation surface of the workpiece.

### FIELD OF THE INVENTION

The present invention concerns laser machining systems and manufacturing methods that may reduce the amount of ablated material that is redeposited. In particular, the methods of the present invention may allow for laser machining of delicate devices that are intolerant to ultrasonic cleaning.

### BACKGROUND OF THE INVENTION

In the field of high frequency electronic circuit design, gallium arsenide (GaAs) microwave monolithic integrated circuits (MMIC's) were demonstrated in the 1970's. Since then, many resources have been put into extending the maximum operating frequency (fₘₐₓ) of GaAs products (e.g., MESFET, PHEMT, HEMT, and HBT technologies) into the hundreds of gigahertz (GHz). However, due to its superior material properties, Gallium nitride (GaN) may provide a superior alternative GaAs. GaN may offer, for example, higher efficiency and a higher operating voltage with lower current, thereby allowing the design of circuitry with approximately ten times the power density of a GaAs PHEMT.

The choice of substrates on which to grow GaN-based MMIC's is an important factor in device performance. It may be desirable, for example, to provide a substrate with low electrical conductivity to limit RF losses through the substrate to ground (i.e., a non-insulating substrate is equivalent to a lossy transmission line to ground at high frequencies). Accordingly, materials such as sapphire or SiC may be used as substrates for GaN devices. Sapphire is a particularly attractive candidate for substrate material due to its cost effectiveness and low-loss characteristics.

However, MMIC's desirably incorporate via holes through the substrate to provide adequate ground contacts to a backside metallization formed thereon. Additionally, such vias may desirably provide thermal contact to assist in heat dissipation from the MMIC to the package. For a sapphire substrate, for example, 8 to 10 via holes having diameters between 30 and 60 μm may be desired per 1 mm² chip. This adds up to approximately 60,000 vias for a standard 4 inch (˜100 mm) wafer, and approximately 150,000 vias for a standard 6 inch (˜150 mm) wafer. Due to sapphire's materials characteristics, however, it may be cost prohibitive, inefficient, and generally undesirable to mechanically machine 60,000 to 150,000 via holes approximately 100 μm or deeper into sapphire substrates using standard machining techniques.

A laser machining method to produce these vias was disclosed in U.S. patent application Ser. No. 11/194,419, “VIA HOLE MACHINING IN MICROWAVE MONOLITHIC INTEGRATED CIRCUITS” (assigned to Matsushita Electric industrial Co., Ltd.), which is incorporated by reference herein.

Laser ablation typically leads to the generation of debris that may be redeposited on the workpiece that is being ablated. Typically, this debris may be removed by ultrasonic cleaning. However, ultrasound may damage some devices that include delicate and/or brittle structures, such as the gate insulators of micron scale transistors included in MMIC's.

Exemplary embodiments of the present invention involve laser machining systems and methods specifically aimed at reducing the amount of debris that is redeposited during laser ablation, thus obviating the ultrasonic cleaning step.

### SUMMARY OF THE INVENTION

An exemplary embodiment of the present invention is a laser machining system adapted to reduce redeposition of material ablated from a workpiece. The laser machining system includes: a laser source to generate a pulsed laser beam; optics to relay the pulsed laser beam along a beam path from the laser source to the work piece; a long working distance objective disposed in the beam path; a workpiece holder to hold the workpiece such that an ablation surface of the workpiece is substantially vertical; and a vacuum chamber, including a window that is substantially transmissive to the laser beam. The vacuum chamber is sized and arranged such that the window in disposed in the beam path and the vacuum chamber encloses the workpiece holder in a reduced pressure environment. The long working distance objective substantially focuses the laser beam to a beam spot on an ablation surface of the workpiece.

Another exemplary embodiment of the present invention is a method of reducing redeposition of material ablated from a workpiece. The workpiece is mounted in a vacuum chamber such that an ablation surface of the workpiece is substantially vertical. The air pressure inside the vacuum chamber is reduced to less than or equal to a predetermined pressure. Pulses of laser light are substantially focused to a beam spot on the ablation surface of the workpiece to ablate material of the workpiece from a portion of the ablation surface within the beam spot.

A further exemplary embodiment of the present invention is a method of manufacturing an integrated circuit (IC) on a sapphire or SiC substrate that has a first surface and a second surface. The IC including an electrode extending through a via in the substrate. Electronic circuit elements are formed on the first surface of the substrate. At least one of these electronic circuit elements is intolerant to ultrasonic processing. The sapphire or SiC substrate with the electronic circuit elements formed on its first surface is mounted in a vacuum chamber such that the second surface of the substrate is substantially vertical. The air pressure inside the vacuum chamber is reduced to less than or equal to a predetermined pressure. Pulses of laser light are substantially focused to a beam spot in a via location on either the first surface or the second surface of the substrate. Each substantially focused pulse of laser light ablates material from the sapphire or SiC substrate without significant redeposition of ablated material on the substrate or the electronic circuit elements. The beam spot of the substantially focused pulses of laser light is scanned over the via location until the via extends from the first surface of the substrate to the second surface of the substrate. The electrode is formed in the via without ultrasonically cleaning the substrate or the electronic circuit elements.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawing are the following figures:

FIG. 1 is a schematic block diagram illustrating an exemplary laser machining system according to the present invention.

FIG. 2 is a schematic block diagram illustrating an alternative exemplary laser machining system according to the present invention.

FIG. 3 is a flowchart illustrating an exemplary method of reducing redeposition of material ablated from a workpiece according to the present invention.

FIG. 4 is a side plan drawing illustrating an exemplary microwave monolithic integrated circuit that may be manufactured using exemplary methods of the present invention.

FIG. 5 is a flowchart illustrating an exemplary method of manufacturing an integrated circuit (IC) on a sapphire substrate that includes an electrode extending through a via in the sapphire substrate according to the present invention.

### DETAILED DESCRIPTION OF THE INVENTION

Typically, laser machining is performed in air for low cost and convenience. During laser ablation, material of the workpiece is irradiated by extremely intense pulses of laser energy. This material become disassociated from the work piece (and often ionized) and is ejected from the surface of the workpiece at high speeds. When the ablation is performed in air, the ablated material may be in the form of a fluid and/or micro-particles. Molecules of the fluid or micro-particles may collide with molecules in air and lose their kinetic energy. As a result, electrostatic attraction (or gravity) may cause a significant percentage of the ablated material to be redeposited on the workpiece in the area being ablated, which may impact the ablation rate, or in the area surrounding the area being ablated, which may affect the operation of the device be manufactured, if this material is not cleaned off of the surface. Because of the size scale of this redeposited debris, even van der Waals forces may lead to relatively strong adhesion, which may make cleaning this debris off of the surface difficult. Typically, an ultrasonic bath is used to remove this redeposited ablation material debris. However, in some applications, ultrasonic cleaning is undesirable due to the potential of damaging the device, e.g. gate insulators in transistors, cantilever elements of micro electrical mechanic systems (MEMS), photonic crystal structures, etc.

The undesired effects of gravity, regarding redeposition of ablated material, may be eliminated by mounting the workpiece in the laser machining system so that the surface to be ablated in substantially vertical and gravity tends to pull the ablated material parallel to the surface of the workpiece instead of toward the workpiece. It is noted that is it not usually desirable for the workpiece to be mounted so that the surface to be ablated in facing downward. Although this configuration would mean that gravity pulled the ablated material away from the workpiece, it would also mean that the ablated material would tend to be deposited on the last optical element of the laser machining system (usually the objective lens). Such deposition would be highly undesirable, as the ablated material is absorptive to the laser pulses of the laser machining system.

Further, by reducing the air pressure at which the laser ablation is performed the mean free path length (MFP) of micro-particles (or fluid) of the ablated material may be increased. Thus, most the fluid and/or micro-particles of the ablated material should be farther from the surface of the workpiece before it loses a significant portion of its kinetic energy and, desirably, beyond the range at which electrostatic attraction would be sufficient cause the material to be redeposited on the workpiece.

Based on this idea, tests have been performed by the inventors. These tests involve drilling via holes in a sapphire substrate in a low vacuum. These tests demonstrate a significant reduction in redeposited debris on the substrate surface. Additionally, the sapphire ablation rate in the low vacuum was ˜10% higher than the sapphire ablation rate in air. Because these effects resulted from using merely a low vacuum, these tests demonstrate that the exemplary methods of the present invention may be implemented relatively easily.

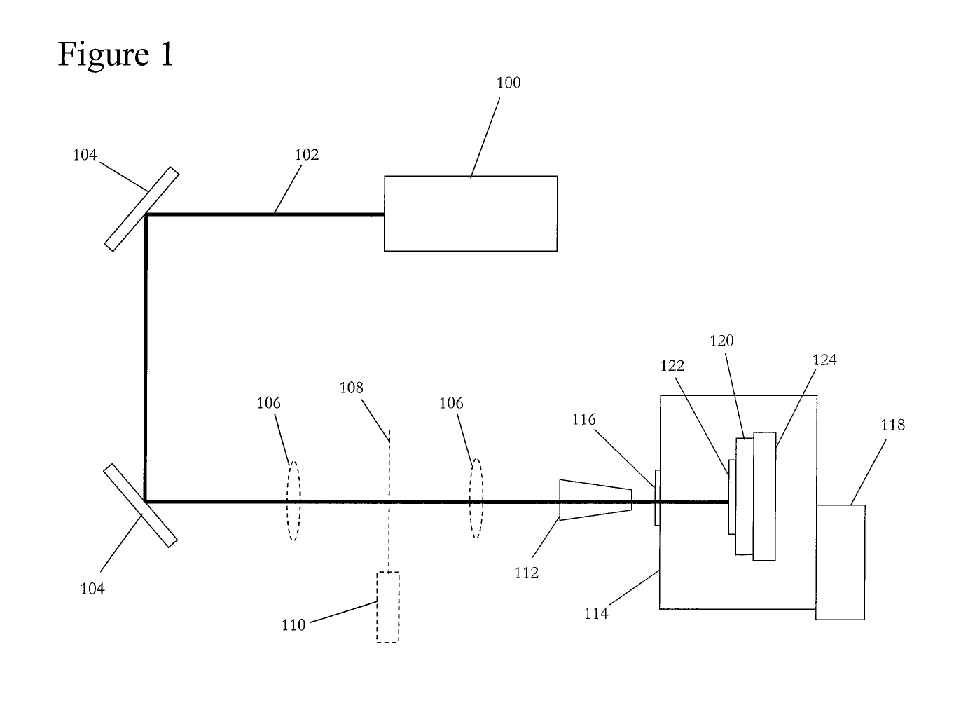

FIG. 1 illustrates an exemplary laser machining system of the present invention. This exemplary laser machining system adapted to reduce redeposition of material ablated from workpiece 122, and includes: laser source 100 to generate a pulsed laser beam; optics to relay the pulsed laser beam along beam path 102 from laser source 100 to work piece 122; long working distance objective 112 disposed in beam path 102; workpiece holder 120 to hold workpiece 122 such that its ablation surface is substantially vertical; and vacuum chamber 114, including substantially transmissive window 116.

Laser source 100 may be any laser source typically used in laser machining applications, for example an ultrafast Ti:sapphire laser. This laser source may include elements such as a frequency doubling crystal and optics to control pulse gating, intensity, and/or polarization.

The relay optics may include free space optical elements, as shown in FIG. 1, or may include an optical fiber link as well. In FIG. 1, the relay optics include mirrors 104 to align beam path 102. One skilled in the art will understand that many optical elements may be included in exemplary embodiments of the present invention as well. For example, U.S. patent application Ser. No. 11/194,419 discloses a number of other optical elements that may be included in laser machining systems, including elements for alignment and for monitoring the machining process.

The relay optics may additionally include elements to scan the beam spot formed by long working distance objective 112 over the ablation surface of workpiece 122. FIG. 1 illustrates one such alternative exemplary scanning means in dashed lines. This exemplary scanning means includes lenses 106, mask 108, and translation stage 110. The first lens 106 substantially focuses the pulses of laser light on a pinhole in mask 108 and the second lens 06 collects light that is transmitted though the pinhole. Translation stage 110 is coupled to mask 108 to translate the pinhole in a plane substantially perpendicular to beam path 102. Translating the pinhole is this manner causes the beam spot on work piece 122 to move a proportional amount. The proportionality is determined by the magnification of long working distance objective 112. Translation stage 110 may be a one-dimensional or a two-dimensional translation stage.

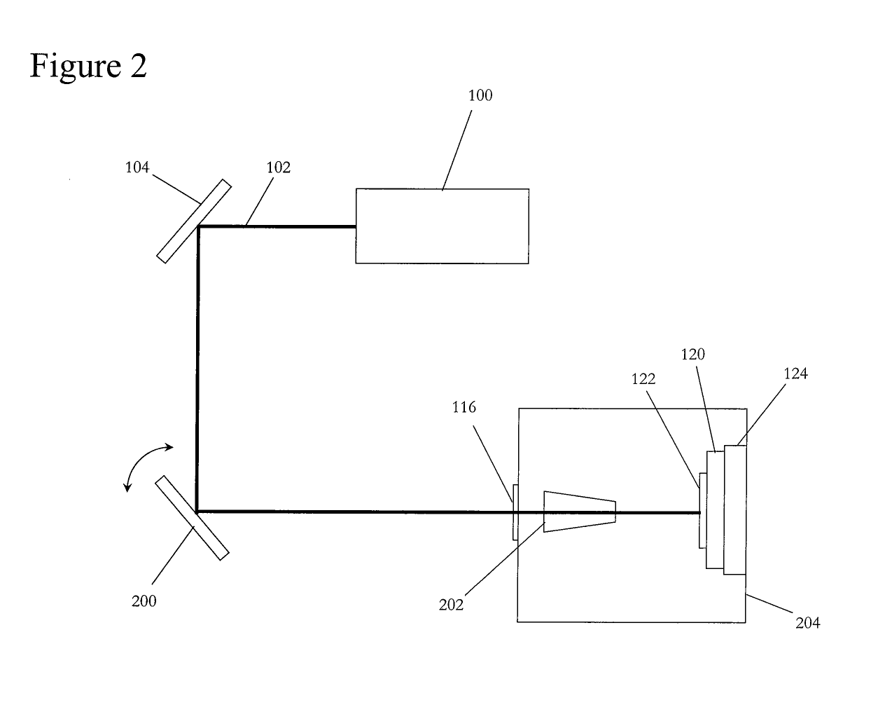

FIG. 2 illustrates another alternative optical scanning means. In this exemplary embodiment the relay optics include scanning mirror 200 and long working distance objective 202, which desirably includes a telecentric optical element, to vary beam path 102 and, thus, scan the beam spot across the ablation surface of workpiece 122 in one transverse direction. It is contemplated that scanning mirror 200 may be replaced with a scanning prism. One skilled in the art will understand that this one-dimensional optical scanning means is merely illustrative and that a similar two-dimensional optical scanning means with two orthogonal scanning mirrors may be used as well. Translation stage 120 may be adapted to provide motion in a direction orthogonal to the scan direction of the illustrated one-dimensional optical scanning means to allow two-dimensional scanning of the beam spot on the ablation surface of workpiece 122.

Returning to the exemplary system of FIG. 1, it is desirable for vacuum chamber 114 to be large enough that window 116 is sufficiently far from the ablation surface of workpiece 122 to limit the amount of ablated material that is deposited on the inner surface of the window. Vacuum chamber 114 also is desirably large enough to accommodate workpiece 122 and workpiece holder 120, which may be directly connected to the back wall of vacuum chamber 114. It may also be desirable for vacuum chamber 114 to accommodate translation stage 124, which may be used to scan and/or focus the beam spot on the ablation surface of workpiece 122. Alternatively, translation stage 118, which is coupled to the outside of vacuum chamber 114, may be used to provide motion for scanning and/or focusing of the beam spot. Focusing of the beam spot may also be accomplished by a focusing means coupled to long working distance objective 112 (not shown). Thus, one skilled in the art will understand that one, or both, of translation stage 118 and translation stage 124 may be omitted.

Vacuum chamber 114 is designed to enclose workpiece 122, and workpiece holder 120, in a reduced pressure environment. This reduced pressure environment desirably reduces redeposition of ablated material on workpiece 122 by increasing the MFP of the material ablated from the workpiece. It is contemplated that an MFP of greater than about 1 mm may significantly reduce this redeposition. Tests conducted by the inventors have demonstrated that a low vacuum may be sufficient to significantly reduce the amount of ablated material redeposited as debris on the workpiece. Therefore, an air pressure of about 5 kPa may be sufficient for the reduced pressure environment of vacuum chamber 114, although an air pressure of about 500 mPa to about 1 mPa may be desirable.

The desire to reduce the amount of ablated material that is deposited on the inner surface of window 116 described above also affects the desired working distance of long working distance objective 112. FIG. 2 illustrates an exemplary embodiment in which vacuum chamber 204 is sized and arranged so as to further enclose long working distance objective 202 in the reduced pressure environment. Although this exemplary embodiment may allow for the use of an objective with a shorter working distance than the exemplary embodiment of FIG. 1, it is still desirable for the working distance of long working distance objective 202 to be sufficiently long to reduce the amount of ablated material deposited on the outer lens surface of long working distance objective 202. Thus, because lower air pressures of the reduced pressure environment result in a longer MFP's for the ablated material, it is contemplated that overly high vacuums may be undesirable in some exemplary embodiments of the present invention.

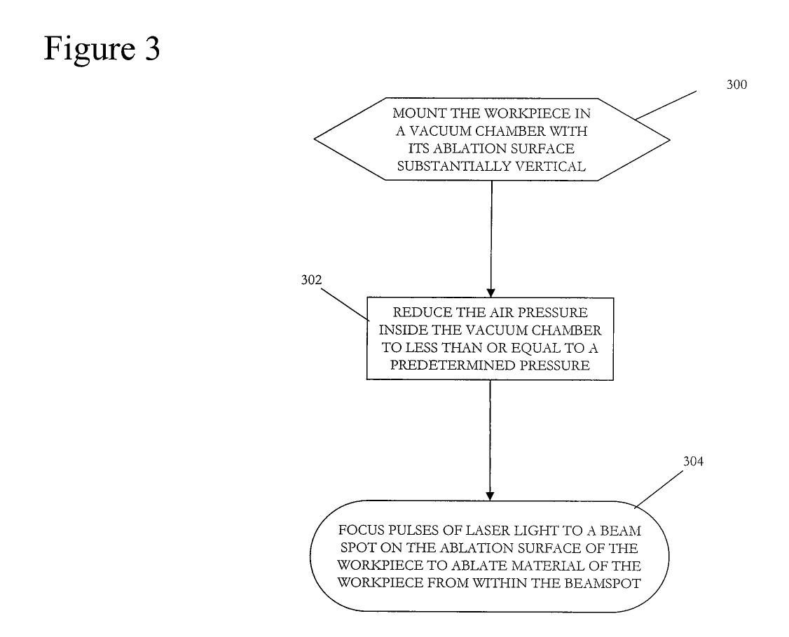

FIG. 3 illustrates an exemplary method of reducing redeposition of material ablated from a workpiece. Although not so limited, it is noted that this exemplary method may be performed using the exemplary laser machining systems of FIGS. 1 and 2.

The workpiece is mounted in a vacuum chamber such that an ablation surface of the workpiece is substantially vertical, step 300. The air pressure inside the vacuum chamber is then reduced to less than or equal to a predetermined pressure, step 302. As described above, the predetermined pressure may be desirably less than about 5 kPa. Alternatively, the desired air pressure of the vacuum chamber may be determined based on certain machining parameters, e.g.: the desired air pressure may be determined to be the pressure at which a MFP of material ablated from the workpiece is greater than about 1 mm; or the desired air pressure may be determined to be the pressure at which the percentage of material ablated from the workpiece that is redeposited on the workpiece is less than about 0.1%.

Pulses of laser light are substantially focused to a beam spot on the ablation surface of the workpiece, step 304. These substantially focused pulses ablate material of the workpiece from a portion of the ablation surface within the beam spot.

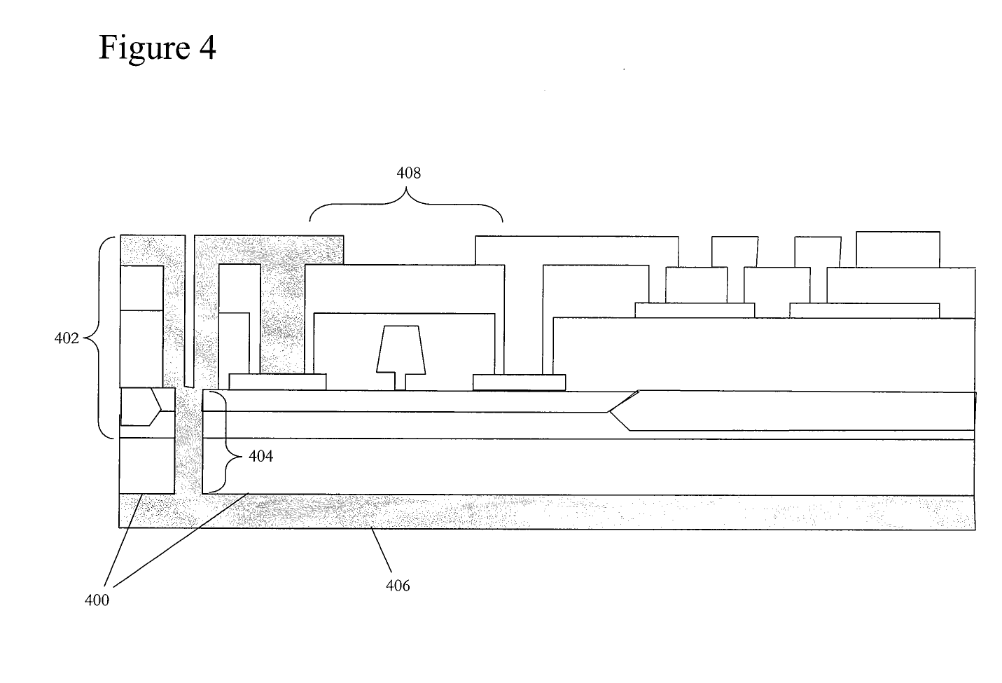

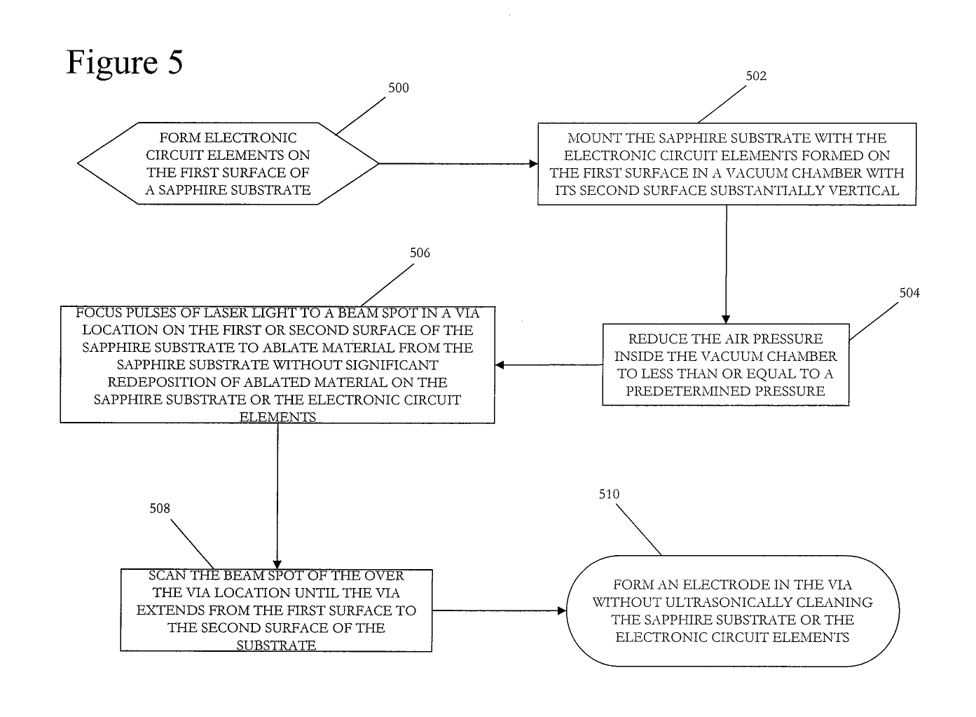

FIG. 5 illustrates an exemplary method of manufacturing an integrated circuit (IC) on a sapphire or SiC substrate that includes an electrode extending through a via in the substrate. As in the exemplary method of FIG. 3, it is noted that this exemplary method may be performed using the exemplary laser machining systems of FIGS. 1 and 2, but that it is not limited to these exemplary systems. FIG. 4 illustrates an exemplary IC that may be manufactured using the exemplary method of FIG. 5.

A plurality of electronic circuit elements 402 are formed on the first surface of sapphire or SiC substrate 400, step 500. At least one of these electronic circuit elements may be intolerant to ultrasonic processing. For example, transistor 408 in the exemplary IC of FIG. 4 may be such an element.

Substrate with electronic circuit elements 402 formed on its first surface in a vacuum chamber such that the second surface of substrate 400 is substantially vertical, step 502. The air pressure inside the vacuum chamber is then reduced to less than or equal to a predetermined pressure, step 504. As in the exemplary method of FIG. 3, this predetermined pressure may be less than about 5 kPa, or it may be determined based on various laser machining parameters.

Pulses of laser light are substantially focused to a beam spot in a via location on either of the first surface or the second surface of substrate 400, step 506. Due to the reduced air pressure in the vacuum chamber, and the orientation of substrate 400, each of the pulses of laser light may ablate material from substrate 400 without significant redeposition of ablated material on either the substrate or electronic circuit elements 402. The beam spot is scanned over the via location until via 404 extends from the first surface of substrate 400 to the second surface, step 508, as shown in FIG. 4.

Electrode 406 is formed in via 404 without ultrasonically cleaning substrate 400 or electronic circuit elements 402, step 510, to complete the exemplary IC.

The present invention includes a number of exemplary embodiments of exemplary laser machining systems and methods of reducing the amount of ablated material that is redeposited on the workpiece during laser machining. Although the invention is illustrated and described herein with reference to specific embodiments, it is not intended to be limited to the details shown. Rather, various modifications may be made in the details within the scope and range of equivalents of the claims and without departing from the invention. In particular, one skilled in the art may understand that many features of the various specifically illustrated embodiments may be mixed to form additional exemplary laser machining systems also embodied by the present invention.

What is claimed:

1. A laser machining system adapted to reduce redeposition of material ablated from a workpiece, the laser machining system comprising:
a laser source to generate a pulsed laser beam;
optics to relay the pulsed laser beam along a beam path from the laser source to the work piece;
a long working distance objective disposed in the beam path to substantially focus the laser beam to a beam spot on an ablation surface of the workpiece;
a workpiece holder to hold the workpiece such that the ablation surface of the workpiece is substantially vertical; and
a vacuum chamber, including a window that is substantially transmissive to the laser beam, the vacuum chamber being sized and arranged such that the window in disposed in the beam path and the vacuum chamber encloses the workpiece holder in a reduced pressure environment.

2. A laser machining system according to claim 1, wherein the optics include a scanning means to scan the beam spot over the ablation surface of the workpiece.

3. A laser machining system according to claim 2, wherein the scanning means includes:
the long working distance objective includes a telecentric optical element; and
one of:
a scanning mirror disposed in the beam path between the telecentric optical element of the long working distance objective and the laser source; or
a scanning prism disposed in the beam path between the telecentric optical element of the long working distance objective and the laser source.

4. A laser machining system according to claim 2, wherein the scanning means includes:
a mask with a pinhole disposed in the beam path between the laser source and the long working distance objective; and
a translation stage coupled to the mask to translate the pinhole in a plane substantially perpendicular to the beam path.

5. A laser machining system according to claim 1, wherein the vacuum chamber is sized and arranged so as to further enclose the long working distance objective in the reduced pressure environment.

6. A laser machining system according to claim 1, wherein an air pressure of the reduced pressure environment is selected such that a mean free path length of the material ablated from the workpiece is greater than about 1 mm.

7. A laser machining system according to claim 1, wherein an air pressure of the reduced pressure environment is less than about 5 kPa.

8. A laser machining system according to claim 1, further comprising a translation stage enclosed in the vacuum chamber and coupled to the workpiece holder to translate the workpiece such that the beam spot is scanned over the ablation surface of the workpiece.

9. A laser machining system according to claim 1, further comprising a translation stage coupled to the vacuum chamber to translate the workpiece such that the beam spot is scanned over the ablation surface of the workpiece.

10. A method of reducing redeposition of material ablated from a workpiece, the method comprising the steps of:
a) mounting the workpiece in a vacuum chamber such that an ablation surface of the workpiece is substantially vertical;
b) reducing the air pressure inside the vacuum chamber to less than or equal to a predetermined pressure; and
c) substantially focusing pulses of laser light to a beam spot on the ablation surface of the workpiece to ablate material of the workpiece from a portion of the ablation surface within the beam spot.

11. A method according to claim 10, wherein the predetermined pressure is less than about 5 kPa.

12. A method according to claim 10, wherein the predetermined pressure is such that a mean free path length of the material ablated from the workpiece in air at the predetermined pressure is greater than about 1 mm.

13. A method according to claim 10, wherein the predetermined pressure is such that a percentage of the material ablated from the workpiece that is redeposited on the workpiece in air at the predetermined pressure is less than about 0.1%.

14. A method of manufacturing an integrated circuit (IC) on a sapphire or SiC substrate having a first surface and a second surface, the IC including an electrode extending through a via in the sapphire or SiC substrate, the method comprising the steps of:
a) forming a plurality of electronic circuit elements on the first surface of the sapphire or SiC substrate, at least one of the plurality of electronic circuit elements being intolerant to ultrasonic processing;
b) mounting the sapphire or SiC substrate with the plurality of electronic circuit elements formed on the first surface in a vacuum chamber such that the second surface of the sapphire or SiC substrate is substantially vertical;
c) reducing the air pressure inside the vacuum chamber to less than or equal to a predetermined pressure;
d) substantially focusing pulses of laser light to a beam spot in a via location on one of the first surface of the sapphire or SiC substrate or the second surface of the sapphire or SiC substrate, each substantially focused pulse of laser light ablating material from the sapphire or SiC substrate without significant redeposition of ablated material on the sapphire or SiC substrate or the plurality of electronic circuit elements;
e) scanning the beam spot of the substantially focused pulses of laser light over the via location until the via extends from the first surface of the sapphire or SiC substrate to the second surface of the sapphire or SiC substrate; and
f) forming the electrode in the via without ultrasonically cleaning the sapphire or SiC substrate or the plurality of electronic circuit elements.

15. A method according to claim 14, wherein the predetermined pressure is less than about 5 kPa.

16. A method according to claim 14, wherein the predetermined pressure is such that a mean free path length of the material ablated from the sapphire or SiC substrate in air at the predetermined pressure is greater than about 1 mm.
